(19) United States
(12) Patent Application Publication
(10) Pub. No.: US 2009/0179316 A1
(43) Pub. Date: Jul. 16, 2009

(54) FLEXIBLE SEMICONDUCTOR DEVICE AND FABRICATION METHOD THEREOF

(75) Inventors: Tao Wang, Taipei (TW); Shey-Shi Lu, Taipei (TW)

Correspondence Address: PEARNE & GORDON LLP, 1801 EAST 9TH STREET, SUITE 1200, CLEVELAND, OH, 44114-3108, US

(73) Assignee: NATIONAL TAIWAN UNIVERSITY, Taipei (TW)

(21) Appl. No.: 12/139,646

(22) Filed: Jun. 16, 2008

(30) Foreign Application Priority Data
Jan. 10, 2008 (TW) 097100948

(51) Int. Cl. H01L 23/495; H01L 21/00

(52) U.S. Cl. 257/676; 438/124; 257/E23.031; 257/E21.001

(57) ABSTRACT

A flexible semiconductor device and a fabrication method thereof are disclosed. The method includes the steps of providing a CMOS (complementary metal-oxide semiconductor) chip having a silicon substrate, wherein an IC (integrated circuit) is formed on the silicon substrate; mounting the chip on a carrier board via the IC-laden side of the chip, wherein the IC-laden side of the chip is in contact with the carrier board; thinning the silicon substrate; forming a resilient plastic layer made of PDMS (polydimethylsiloxane) on the thinned silicon substrate; and removing the carrier board. The chip is flexible enough to expose testing pads on the front of the chip so as to facilitate wire bonding and probing. The resilient plastic layer enables uniform distribution of stress exerted on the chip and thereby guards the chip from cracking.

### FIELD OF THE INVENTION

The present invention relates to semiconductor devices and methods, and more particularly, to a flexible chip and a fabrication method thereof.

### BACKGROUND OF THE INVENTION

Conventional flexible chips are mainly OFETs (organic field-effect transistors). The major difference between the OFET and the mainstream CMOS (complementary metal oxide semiconductor) transistor is that, in the OFET type, the inorganic silicon and silica materials of the MOSFET (metal-oxide semiconductor field effect transistor) are replaced with organic semiconductor materials. The substrate in the OFET type possesses softness of the polymer it utilizes so as to be applied in flexible chips.

The general structure of the OFET includes one layer of polymer as a substrate, which is used as a charge channel after doping, and the process of making the OFET includes: forming a drain and a source on the organic substrate; defining one layer of silica below the substrate as an insulating layer for gate modulation; and forming a gate below the insulating layer to control the electrical conductivity of the charge channel. The substrate doping in the OFET is mainly of the P-Substrate at present, and the transport mechanism of the transistor is accumulation mode.

However, in the present technology, the OFET has a choke point due to the low operating frequency of such elements that results from a low charge mobility in the organic matter. Although the charge mobility of the present P-Substrate is up to 1.5 cm²/V-S, which is similar to the polycrystalline silicon, it has difficulties in application in high speed circuits. As for the N-Substrate, the charge mobility is much lower than that of the P-Substrate. Therefore, the drawback described above influences the practicability of applying OFETs to high-frequency circuits, such as radio frequency circuits and central processing units. Moreover, other drawbacks of such OFETs include an inadequate ON/Off ratio, leakage currents for the elements, high operating voltage (−20˜−50V), and limited reliability.

In light of the foregoing drawbacks, the industry developed other methods to fabricate flexible chips, wherein the STT (substrate transfer technology) technique is the most mature technology. In STT, a chip fabricated by the SOI (silicon on insulator) technology is provided. The chip is further coated with polyimide on the front thereof, and subsequent processes are performed, such as removal of the silicone substrate of the chip by chip grinding and wet etching.

FIGS. 1A to 1C are schematic views showing the stepwise processes of the known substrate transfer technology. Referring to FIG. 1A, a chip 10 fabricated by the SOI technology is provided, which includes a silicon substrate 101, silica layer 102, and circuit layer 103. A polymer 11 is further coated on the circuit layer 103 on the front of the chip 10. Referring to FIG. 1B, a glass substrate 13 is adhered to the front of the chip 10 via an adhesion layer 12. Referring to FIG. 1C, the chip 10 is reversed and the silicon substrate 101 on the back of the chip 10 is ground down to around 100 μm. The silicon substrate 101 is then removed and the chip is cut by potassium hydroxide (KOH) wet etching so as to use the thin polymer 11 as a substrate to form a flexible chip 10′.

In the SOI process of the STT technique described above, a silicon element is employed. However, the silica layer between the circuit layer and the silicon substrate is incompatible with present mainstream CMOS chips. Further, the silica layer is the potassium hydroxide wet etching mask, and it can't be removed in the process, resulting in difficulties of system integration. As a result, material cost is increased and the application field is limited.

Moreover, in conventional substrate transfer technology, the polymer is adhered to the front of the chip so as to encapsulate the testing pads of the chip circuit, resulting in difficulties with wire bonding and probing in terms of electrical contact.

Furthermore, after the chip is completed, the polymer substrate is too thin to support the chip. Therefore, the chip is liable to cracking as a result of non-uniform stresses applied to the chip during wire bonding and probing.

Therefore, there exists a strong need in the art for a flexible semiconductor device and a fabrication method thereof to avoid difficulties encountered during wire bonding and probing as a result of encapsulated testing pads of the chip circuit, as well as to prevent chip cracking as a result of non-uniform stresses applied to the chip during wire bonding and probing, provide good electrical properties so as to be applicable in high speed circuits, and integrate with the present mainstream CMOS process technology.

### SUMMARY OF THE INVENTION

In light of the foregoing drawbacks of the prior art, a primary objective of the present invention is to provide a flexible semiconductor device and a fabrication method thereof that is capable of preventing the chip from cracking as a result of the application of non-uniform stresses.

Another objective of the present invention is to provide a flexible semiconductor device and a fabrication method thereof that is capable of avoiding difficulties encountered in performing wire bonding and probing that exist as a result of the encapsulated testing pads of the chip circuit in the prior art.

Another objective of the present invention is to provide a flexible semiconductor device and a fabrication method thereof to provide good electrical properties so as to be applicable in high-speed circuits.

Another objective of the present invention is to provide a flexible semiconductor device and a fabrication method thereof that is capable of being integrated with CMOS chip technology, which is the mainstream technology of present systems.

In order to achieve the above and other objectives, the present invention discloses a flexible semiconductor device, including: a chip having a thinned silicon substrate and an IC formed on the thinned silicon substrate; and a resilient plastic layer formed on the thinned silicon substrate side of the chip.

In the above structure, the chip is a CMOS chip; the resilient plastic layer is made of organic polymer such as PDMS (polydimethylsiloxane); and the thickness of the thinned silicon substrate is 10 to 20 μm. Moreover, the PDMS is subjected to hard baking to adhere to the chip and present as silicon gel, by which flexibility of the chip is realized. Also, this construction uniformly distributes stresses applied to the chip, preventing the chip from cracking.

The present invention further discloses a fabrication method of a flexible semiconductor device, including the steps of: providing a chip having a silicon substrate and an IC (integrated circuit) formed on the silicon substrate, wherein the chip is mounted on a carrier board via the IC-laden side of the chip; thinning the silicon substrate of the chip; forming a resilient plastic layer on the silicon substrate, wherein the resilient plastic layer is connected to the chip; and removing the carrier board.

In the above fabrication method, the chip is a CMOS (complementary metal oxide semiconductor) chip, and the chip is mainly made of inorganic material so that, relative to the ones made of organic material, the electrical properties thereof are suitable to be applied in high-speed circuits; and the resilient plastic layer is made of organic polymer such as PDMS (polydimethylsiloxane).

The silicon substrate is subjected to dry etching by inductive coupling plasma etching, and the dry etching time is controlled to thin the silicon substrate to a thickness of 10 to 20 μm. Moreover, the PDMS is coated on the silicon substrate and then baked to adhere to the chip and present as silicon gel. After removing the carrier board, the chip is flexible as a result of the flexibility of the PDMS.

In addition, in the flexible semiconductor device and the fabrication method thereof of the present invention, wherein the chip is mounted on a carrier board via the front of the chip for thinning the silicon substrate on the back of the chip; the silicon substrate thereon, subsequently, is coated by a resilient plastic layer which is capable of dispersing the stresses of wire bonding and probing applied to the chip, consequently strengthening the chip from cracking during such operations; and, finally, the carrier board is removed. In this design, the testing pads on the front of the chip are not encapsulated by the resilient plastic layer, such that the operations of wire bonding, probing and so on may be conducted without interference.

In summary, compared with conventional chip designs and processes, the present invention, which uses mainstream CMOS chip technology, is low cost, compatible with mainstream systems, convenient to test, and broadly applicable. Accordingly, the present invention provides chips with flexibility to overcome the drawbacks of the prior art.

### BRIEF DESCRIPTION OF THE DRAWINGS

The present invention can be more fully understood by reading the following detailed description of the preferred embodiments, with reference made to the accompanying drawings, wherein:

FIGS. 1A to 1C are cross-sectional views showing the stepwise processes of the conventional substrate transfer technology; and

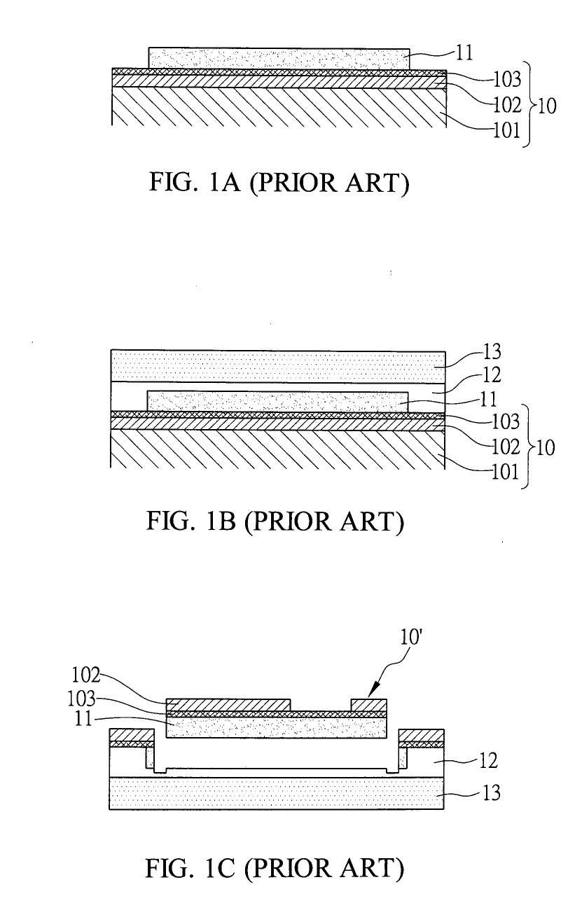

FIGS. 2A to 2D are cross-sectional views showing the flexible semiconductor device and the fabrication method thereof according to the present invention.

### DETAILED DESCRIPTION OF THE PREFERRED EMBODIMENTS

The following specific embodiments with reference made to the accompanying drawings are provided to illustrate the present invention. Others skilled in the art can readily gain an insight into other advantages and features of the present invention based on the contents disclosed in this specification.

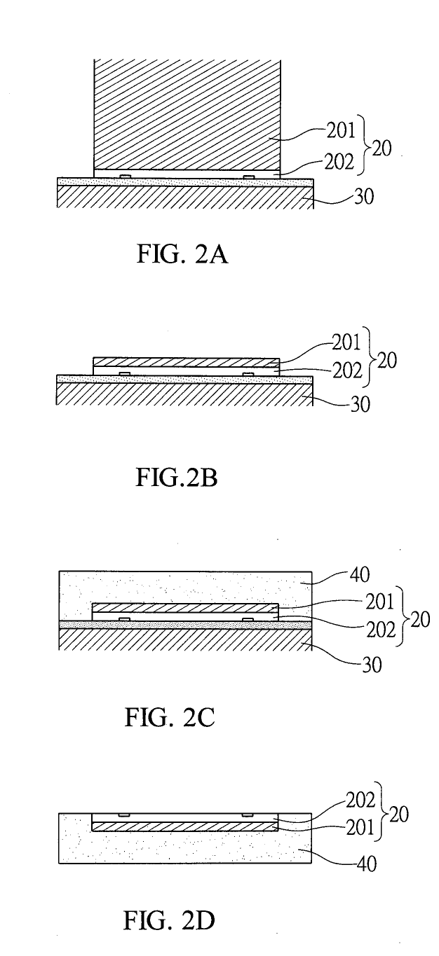

FIGS. 2A to 2D are cross-sectional views showing the flexible semiconductor device and the fabrication method thereof according to the present invention. Referring to FIG. 2A, a CMOS chip 20 is provided, wherein the chip 20 includes a silicon substrate 201 and an IC (integrated circuit) 202 formed on the silicon substrate 201, and the chip 20 is mounted on a carrier board 30 such as a silicon wafer via the IC 202-laden side of the chip 20. The silicon substrate 201 side of the chip 20 is outward. There are a plethora of CMOS process technologies that are known in the industry, but such are not the technical features of the present invention, so such processing technologies will not be further detailed herein.

Referring to FIG. 2B, the silicon substrate 201 is subsequently thinned by dry etching using inductive coupling plasma. The dry etching time is controlled to thin the silicon substrate 201 to a thickness of 10 to 20 μm. Dry etching is used to precisely control the thickness of the silicon substrate 201 and prevent the IC 202 of the chip 20 from damage.

Referring to FIG. 2C, a resilient plastic layer 40 made of such as organic polymer is then coated on the silicon substrate 201. A further example of the resilient plastic layer 40 is PDMS (polydimethylsiloxane). The PDMS is baked to adhere to the chip 20 and to present as silicone gel.

Referring to FIG. 2D, the carrier board 30 is removed from the chip 20, and the resulting chip 20 is flexible as a result of the flexibility of the PDMS.

Referring again to FIG. 2D, a flexible semiconductor device of the present invention is further provided. The flexible semiconductor device includes a chip 20 and a resilient plastic layer 40, wherein the chip 20 includes a thinned silicon substrate 201 and an IC 202 formed on the thinned silicon substrate 201. The resilient plastic layer 40 is connected to the thinned silicon substrate 201 side of the chip 20; and the resilient plastic layer 40 is connected to the chip 20.

In the above structure, the chip 20 is a standard CMOS chip.

The resilient plastic layer 40 is made of organic polymer such as PDMS. The thickness of the thinned silicon substrate 201 is 10 to 20 μm, and the thinned chip 20 is adhered to the PDMS, which presents as silicone gel so as to afford the thinned chip 20 a supporting structure. The flexibility of the PDMS further affords the thinned chip 20 flexibility and prevents the chip 20 from cracking.

The fabrication method of the flexible semiconductor device according to the present invention employs a CMOS chip to be subjected to a post-processing treatment, and therefore it is suitable for any chip. The fabrication method of the present invention reduces the material cost, and the flexible semiconductor device therefrom can be integrated into mainstream systems so as to be broadly applicable.

Further, the dry etching is employed according to the present invention to precisely control the thickness of the etched silicon substrate 201 to be quite-thin (10 to 20 μm), thereby preventing the IC 202 of the chip 20 from damage due to the precision. Additionally, the chip 20 is flexible after the silicon substrate 201 is thinned. Moreover, according to the present invention, the PDMS is employed to substitute for the silicon substrate 201 and is evenly coated on the back of the chip 20. Therefore, the testing pads of the IC 202 are unencapsulated so as to avoid difficulties with wire bonding and probing. Also, the flexibility of the PDMS results in a uniform distribution of the stresses incurred during wire bonding and probing on the front of the chip 20 so as to prevent the flexible chip 20 from cracking.

In conclusion, the flexible semiconductor device and the fabrication method thereof according to the present invention employ PDMS adhered to the silicon substrate side of the chip to afford the chip greater flexibility and to prevent the chip from cracking. Moreover, compared with those adopting the known chip of certain prior-art processes, the present invention, which uses the present mainstream CMOS chip, is low cost, compatible with mainstream systems, convenient to test, and broadly applicable. Also, the present invention affords conventional chips with flexibility to overcome the drawbacks of the prior art.

The present invention has been described using exemplary preferred embodiments above; however, it is to be understood that the scope of the present invention is not limited to the disclosed embodiments. On the contrary, it is intended to cover various modifications and similar changes. It will be apparent to those skilled in the art that any equivalent modifications or changes made without departing from the spirit and the technical concepts disclosed by the present invention should fall within the scope of the appended claims.

What is claimed is:

1. A fabrication method of a flexible semiconductor device, comprising the steps of:
providing a chip having a surface with a silicon substrate and an IC formed on the silicon substrate, wherein the chip is mounted on a carrier board via the surface of the chip;
thinning the silicon substrate of the chip;
forming a resilient plastic layer on the silicon substrate; and
removing the carrier board.

2. The fabrication method of claim 1, wherein the chip is a CMOS chip.

3. The fabrication method of claim 1, wherein the silicon substrate is thinned by dry etching.

4. The fabrication method of claim 3, wherein the dry etching is inductive coupling plasma etching.

5. The fabrication method of claim 3, wherein a duration of the dry etching is controlled to obtain a desired thickness of the silicon substrate.

6. The fabrication method of claim 1, wherein the silicon substrate is thinned to a thickness between 10 to 20 μm.

7. The fabrication method of claim 1, wherein the resilient plastic layer is made of organic polymer.

8. The fabrication method of claim 7, wherein the resilient plastic layer is made of PDMS.

9. The fabrication method of claim 8, wherein the PDMS is baked to adhere to the chip and to present as silicone gel to be flexible.

10. The fabrication method of claim 1, wherein the carrier board is a silicon wafer.

11. A flexible semiconductor device, comprising:
a chip having a thinned silicon substrate and an IC formed on the thinned silicon substrate; and
a resilient plastic layer formed on the silicon substrate side of the chip.

12. The flexible semiconductor device of claim 11, wherein the chip is a CMOS chip.

13. The flexible semiconductor device of claim 11, wherein a thickness of the thinned silicon substrate is 10 to 20 μm.

14. The flexible semiconductor device of claim 11, wherein the thinned silicon substrate is formed by dry etching.

15. The flexible semiconductor device of claim 14, wherein the dry etching is inductive coupling plasma etching.

16. The flexible semiconductor device of claim 14, wherein a duration of the dry etching is controlled to obtain a desired thickness of the thinned silicon substrate.

17. The flexible semiconductor device of claim 11, wherein the resilient plastic layer is made of organic polymer.

18. The flexible semiconductor device of claim 17, wherein the organic polymer is PDMS.

19. The flexible semiconductor device of claim 18, wherein the organic polymer adheres to the chip and presents as silicone gel to be flexible.
